(19) United States
(12) Patent Application Publication
(10) Pub. No.: US 2016/0146873 A1
(43) Pub. Date: May 26, 2016

(54) TESTING DEVICE OF SIGNALING MODE AND TESTING METHOD THEREOF

(71) Applicant: ALIFECOM TECHNOLOGY CORP., Taipei City (TW)

(72) Inventors: Meng-Kai SU, Taipei City (TW); Yi-Chung SHEN, Taipei City (TW); Shih-Hsiang HU, Taipei City (TW); Heng-Iang HSU, Taipei City (TW); Shu-Hua KAO, Taipei City (TW); Daching CHEN, Taipei City (TW)

(21) Appl. No.: 14/552,835

(22) Filed: Nov. 25, 2014

(51) Int. Cl. G01R 31/02

(52) U.S. Cl. CPC G01R 31/02

(57) ABSTRACT

A testing device of a signaling mode and a testing method thereof are provided. The testing device includes a connecting module and a processor electrically connected to the connecting module. The connecting module is configured to electrically couple with a plurality of communication devices under tests (DUTs) simultaneously. The processor is configured to execute a network attaching procedure between the testing device and each of the communication DUTs, wherein the network attaching procedures are overlapped to be executed. The processor is further configured to test the communication DUTs after executing the network attaching procedures.

### FIELD

The present invention relates to a testing device and a testing method thereof. More particularly, the present invention relates to a testing device of a signal mode and a testing method thereof.

### BACKGROUND

Communication devices (e.g., mobile phones, notebook computers, tablet computers, personal digital assistants (PDAs) or the like) must be subjected to a number of tests before shipment. Currently, a testing device for testing communication devices are generally classified into the non-signaling mode and the signaling mode. For the non-signaling mode, the testing devise does not need to execute a network attaching procedure with a communication device under test (DUT) before the communication DUT is tested. In addition, the user has to control the testing device and the communication DUT simultaneously during the test. For the signaling mode, the testing devise has to execute a network attaching procedure with the communication DUT before the communication DUT is tested. In addition, the user only needs to control the testing device during the test.

As the demand for communication devices has increased dramatically over recent years, the production of communication devices has also accelerated exponentially. Modem communication devices are required to deliver rich quality features and fast connection speed. Therefore, their embedded protocol software and transceiver hardware have evolved to become extremely complex, with intertwined impact on each other never seen before. This has driven modern communication devices to have many different operation modes, each optimized for a specific scenario, in order to utilize the limited spectrum resources more efficiently while maintaining the best quality of service.

However, a conventional testing device of the signaling mode cannot handle a plurality of communication DUTs simultaneously. Once a plurality of communication DUTs need to be tested, the conventional testing device has to separately perform the following operations in sequence for each of the communication DUTs: electrically coupling with one communication DUT; executing a network attaching procedure with the communication DUT; and making a test on the communication DUT. In other words, before those operations are performed on the current communication DUT, the conventional testing device cannot execute those operations on the next communication DUT. Thus, the time spent in testing N communication DUTs is almost equal to N times of the time spent in testing one communication DUT.

In view of this, it is important to improve the testing efficiency of a conventional testing device of the signaling mode.

### SUMMARY

A primary objective of the present invention includes improving the testing efficiency of a conventional testing device of the signaling mode, and particularly to improve the testing efficiency of the conventional testing device in testing a plurality of communication DUTs.

To achieve the aforesaid objective, certain embodiments of the present invention include a testing device of a signaling mode. The testing device comprises a connecting module and a processor electrically connected with the connecting module. The connecting module is configured to electrically couple with a plurality of communication devices under test (DUTs) simultaneously. The processor is configured to execute a network attaching procedure between the testing device and each of the communication DUTs, wherein the network attaching procedures are overlapped to be executed. The processor is further configured to test the communication DUTs after executing the network attaching procedures.

To achieve the aforesaid objective, certain embodiments of the present invention further include a testing method for use in a testing device of a signaling mode. The testing device comprises a connecting module and a processor electrically connected with the connecting module. The testing method in certain embodiments comprises the steps of:

(a) electrically coupling the connecting module with a plurality of communication DUTs simultaneously;

(b) executing a network attaching procedure between the testing device and each of the communication DUTs by the processor, wherein the network attaching procedures are overlapped to be executed; and

(c) testing the communication DUTs by the processor after executing the network attaching procedures.

In summary, the present invention includes a testing device of a signaling mode and a testing method thereof. Due to the aforesaid connecting module, the testing device is electrically coupled with a plurality of communication DUTs simultaneously to save the time that would otherwise be taken to couple the testing device repeatedly each time a communication device is tested. Due to the aforesaid processor, the network attaching procedure necessary for the plurality of communication DUTs are overlapped to be executed by the testing device to shorten the time necessary for establishing the network connections between the testing device and the plurality of communication DUTs. The testing method is applied to the testing device to implement the aforesaid operations. Consequently, the present invention can effectively improves the testing efficiency of a conventional testing device of the signaling mode.

The detailed technology and preferred embodiments implemented for the present invention are described in the following paragraphs accompanying the appended drawings for persons skilled in the art to well appreciate the features of the claimed invention.

### BRIEF DESCRIPTION OF THE DRAWINGS

FIG. 1 is a schematic view of a testing device of a signaling mode according to an embodiment of the present invention;

FIG. 2 is a schematic view illustrating an example in which the testing device executes sub-procedures with two communication DUTs conforming to the LTE specification according to the first embodiment of the present invention;

FIG. 3 is another schematic view illustrating another example in which the testing device executes sub-procedures with two communication DUTs conforming to the LTE specification according to the first embodiment of the present invention;

FIG. 4 is a schematic view illustrating an example in which the testing device executes a radio resource control connection establishment procedure with four communication DUTs conforming to the LTE specification according to the first embodiment of the present invention; and

FIG. 5 is a flowchart diagram of a testing method for use in a testing device of a signaling mode according to an embodiment of the present invention.

### DETAILED DESCRIPTION

In the following description, the present invention will be explained with reference to certain example embodiments thereof. However, these example embodiments are not intended to limit the present invention to any specific examples, embodiments, environment, applications or particular implementations described in these example embodiments. Therefore, description of these example embodiments is only for the purpose of illustration rather than to limit the present invention.

In the following embodiments and the attached drawings, elements unrelated to the present invention are omitted from the depiction. In addition, dimensional relationships among individual elements in the attached drawings are illustrated only for the ease of understanding but not to limit the actual scale.

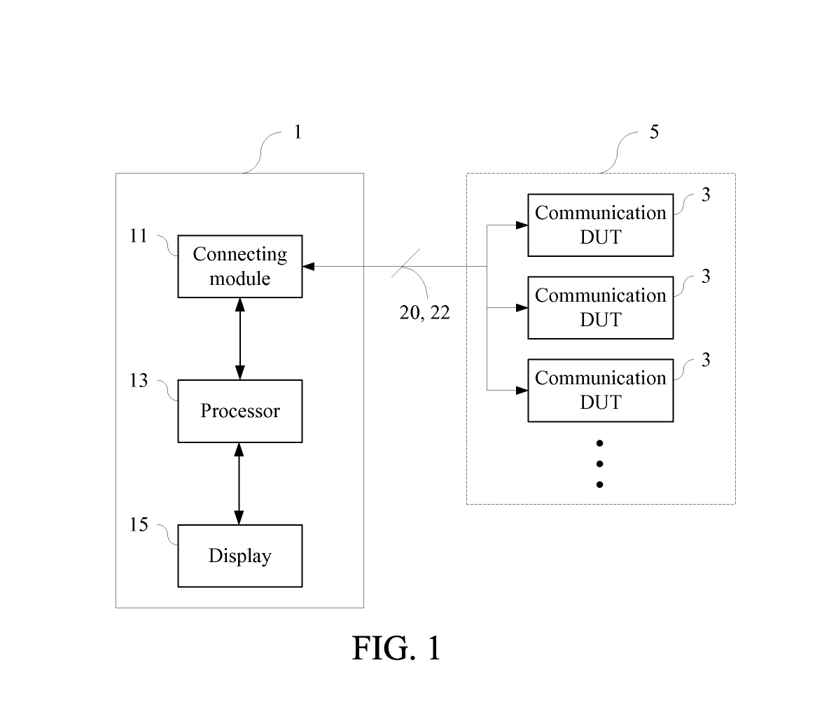

An embodiment of the present invention (briefly called as “the first embodiment” hereinafter) is a testing device of a signaling mode. A schematic structural view of the testing device is show in FIG. 1. As shown in FIG. 1, the testing device 1 comprises a connecting module 11 and a processor 13 electrically connected to the connecting module 11. Unlike a conventional testing device of the signaling mode that must be coupled with one of a plurality of communication DUTs 3 at a time, the connecting module 11 can be configured to electrically couple with the plurality of communication DUTs 3 simultaneously via various connection elements thereof such as one-to-multiple synchronous connecting elements, multiple-to-multiple synchronous connecting elements, or the like. The electric coupling between the connecting module 11 and the plurality of communication DUTs 3 may be performed by wireless coupling or wired coupling, and it means that there are electric signal transmissions between the connecting module 11 and the plurality of communication DUTs 3.

In an example of this embodiment, the connecting module 11 may be electrically coupled with the plurality of communication DUTs 3 via a shielding box 5. Through the shielding effect of the shielding box 5, the plurality of communication DUTs 3 disposed in the shielding box 5 can be free from interferences of various external signals and noises. In this way, the coupling between the connecting module 11 and the plurality of communication DUTs 3 becomes more stable so that the quality of testing the plurality of communication DUTs 3 can be improved. The plurality of communication DUTs 3 may be disposed in a same space in the shielding box 5 or in spaces independent from each other in the shielding box 5. In other embodiments, the connecting module 11 may also be electrically coupled with the plurality of communication DUTs 3 via a splitter or on the air.

The testing device 1 is not limited to any specific communication transmission specification. For example, if the plurality of communication DUTs 3 conform to the Long Term Evolution (LTE) specification, the testing device 1 executes a plurality of network attaching procedures with the plurality of communication DUTs 3 and tests the plurality of communication DUTs 3 according to the LTE specification. If the plurality of communication DUTs 3 conform to the Worldwide Interoperability for Microwave Access (WiMAX) specification, the testing device 1 executes a plurality of network attaching procedures with the plurality of communication DUTs 3 and tests the plurality of communication DUTs 3 according to the WiMAX specification. In other words, the testing device 1 is applicable for the plurality of communication DUTs 3 with various communication transmission specifications.

After the connecting module 11 is electrically coupled with the plurality of communication DUTs 3 simultaneously, the processor 13 executes a network attaching procedure 20 with each of the plurality of communication DUTs 3, which the network attaching procedures 20 are overlapped to be executed. Each of the network attaching procedures 20 generally refers to all the procedure necessary for establishing a network connection between the testing device 1 and the corresponding communication DUT 3.

Each of the network attaching procedures 20 may comprise a plurality of sub-procedures 22. The types, numbers and contents of the sub-procedures 22 may vary with the communication transmission specification of the plurality of communication DUTs 3. Commonly, the sub-procedures 22 of each of the network attaching procedures 20 may comprise a cell selection procedure, a radio connection procedure, a network connection procedure, and a service connection procedure.

For example, if the plurality of communication DUTs 3 conform to the LTE specification, the sub-procedures 22 of each of the network attaching procedures 20 may comprise a cell selection procedure 220 (corresponding to the aforesaid cell selection procedure), a radio resource control (RRC) connection establishment procedure 222 (corresponding to the aforesaid radio connection procedure), a non-access stratum (NAS) attach procedure 224 (corresponding to the aforesaid network connection procedure), and an evolved packet system (EPS) bearer establishment and user equipment internet protocol (UE IP) allocation procedure 226 (corresponding to the aforesaid service connection procedure). The cell selection procedure 220 is executed to inform the plurality of communication DUTs 3 of the start of the network attach procedures 20.

For each of the network attaching procedures 20, the processor 13 executes the sub-procedures 22 in sequence. In an example of this embodiment, the processor 13 may execute corresponding sub-procedures 22 of the network attaching procedures 20 in parallel. That is, the processor 13 simultaneously executes corresponding sub-procedures 22 of the network attaching procedures 20. In another example of this embodiment, the processor 13 may alternately execute corresponding sub-procedures 22 of the network attaching procedures 20.

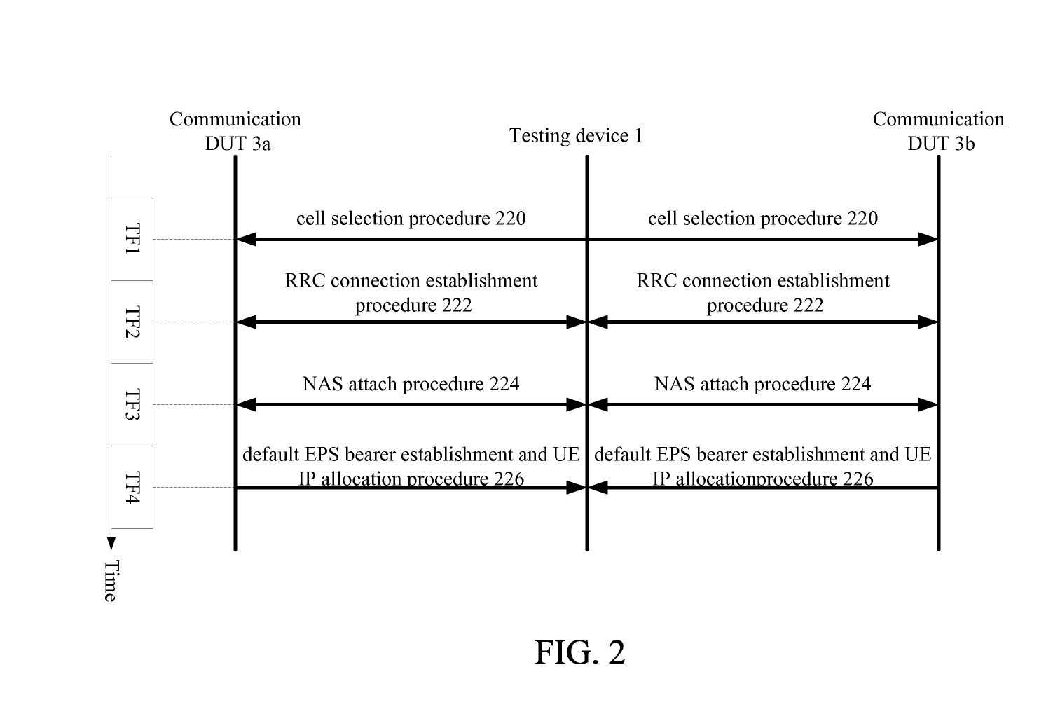

For convenience of the following descriptions, only two communication DUTs (i.e., a communication DUT 3a and a communication DUT 3b) are; however, this is not intended to limit the present invention. FIG. 2 is a schematic view illustrating an example in which the testing device 1 executes the necessary sub-procedures 22 with the communication DUTs 3a, 3b conforming to the LTE specification. As shown in FIG. 2, after the connecting module 11 has been electrically coupled with both of the communication DUT 3a and the communication DUT 3b, the processor 13 may execute sub-procedures 22 (i.e., the cell selection procedure 220, the RRC connection establishment procedure 222, the NAS attach procedure 224, the default EPS bearer establishment and UE IP allocation procedure 226) of a network attaching procedures 20 in sequence with each of the communication DUTs 3a, 3b. In addition, the processor 13 may execute corresponding sub-procedures 22 of the network attaching procedures 20 in parallel.

More specifically, as shown in FIG. 2, the processor 13 may execute the following operations in sequence: performing the cell selection procedure 220 with the communication DUT 3a and the communication DUT 3b in a time frame TF1 in parallel; performing the RRC connection establishment procedure 222 with the communication DUT 3a and the communication DUT 3b in a time frame TF2 (following the frame TF1) in parallel; performing the NAS attach procedure 224 with the communication DUT 3a and the communication DUT 3b in a time frame TF3 (following the frame TF2) in parallel; and performing the default EPS bearer establishment and UE IP allocation procedure 226 with the communication DUT 3a and the communication DUT 3b in a time frame TF4 (following the frame TF3) in parallel. In such a way, the testing device 1 can simultaneously perform each set of corresponding sub-procedures 22 of multiple network attaching procedures 20 with the plurality of communication DUTs 3 in the same time frame.

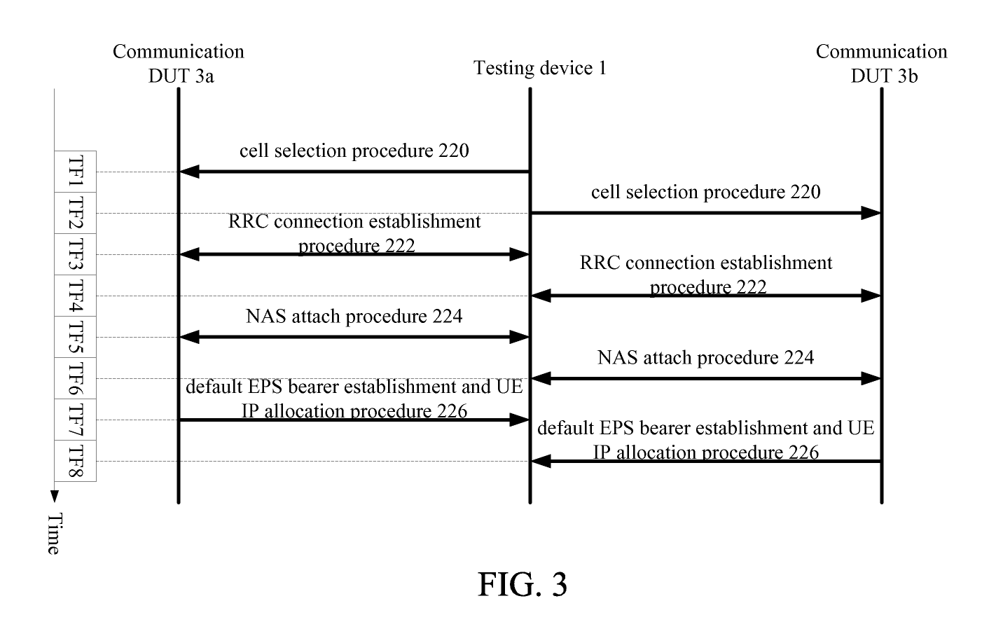

FIG. 3 is a schematic view illustrating another example in which the testing device 1 executes the sub-procedures 22 with the communication DUTs 3a, 3b conforming to the LTE specification. As shown in FIG. 3, after the connecting module 11 has been electrically coupled with both of the communication DUT 3a and the communication DUT 3b, the testing device 1 may execute sub-procedures 22 (i.e., the cell selection procedure 220, the RRC connection establishment procedure 222, the NAS attach procedure 224, the default EPS bearer establishment and UE IP allocation procedure 226) of a network attaching procedure 20 in sequence with each of the communication DUTs 3a, 3b. In addition, the processor 13 may alternately execute corresponding sub-procedures 22 of the network attaching procedures 20.

More specifically, the processor 13 may execute the following operations in sequence: performing the cell selection procedure 220 with the communication DUT 3a in a time frame TF1; performing the cell selection procedure 220 with the communication DUT 3b in a time frame TF2 (following the frame TF1); performing the RRC connection establishment procedure 222 with the communication DUT 3a in a time frame TF3 (following the frame TF2); performing the RRC connection establishment procedure 222 with the communication DUT 3b in a time frame TF4 (following the frame TF3); performing the NAS attach procedure 224 with the communication DUT 3a in a time frame TF5 (following the frame TF4); performing the NAS attach procedure 224 with the communication DUT 3b in a time frame TF6 (following the frame TF5); performing the default EPS bearer establishment and UE IP allocation procedure 226 with the communication DUT 3a in a time frame TF7 (following the frame TF6); and performing the default EPS bearer establishment and UE IP allocation procedure 226 with the communication DUT 3b in a time frame TF8 (following the frame TF7). In such a way, the testing device 1 can perform each set of corresponding sub-procedures 22 of multiple network attaching procedures 20 with the plurality of communication DUTs 3 in near time frames.

The processor 13 may also execute the sub-procedures 22 between the testing device 1 and the communication DUTs 3a, 3b in other interlaced ways. For example, the processor 13 may execute the following operations in sequence: performing the cell selection procedure 220 with the communication DUT 3b in the time frame TF1; performing the RRC connection establishment procedure 222 with the communication DUT 3b in the time frame TF2; performing the cell selection procedure 220 with the communication DUT 3a in the time frame TF3; performing the NAS attach procedure 224 with the communication DUT 3b in the time frame TF4; performing the RRC connection establishment procedure 222 with the communication DUT 3a in the time frame TF5; performing the NAS attach procedure 224 with the communication DUT 3a in the time frame TF6; performing the default EPS bearer establishment and UE IP allocation procedure 226 with the communication DUT 3a in the time frame TF7; and performing the default EPS bearer establishment and UE IP allocation procedure 226 with the communication DUT 3b in the time frame TF8.

As shown in FIG. 2 and FIG. 3, even though the sub-procedures 22 necessary for one communication DUT are not performed completely, the sub-procedures 22 necessary for other communication DUTs can still be executed by the processor 13 to shorten the whole time necessary for creating the connections between the testing device 1 and the plurality of communication DUTs 3.

In an example of this embodiment, each of the sub-procedures 22 may further comprise a plurality of detailed procedures. For example, the RRC connection establishment procedure 222 may comprise the following detailed procedures in sequence: transmitting an RRC connection request message 2220 to the testing device 1 by each of the communication DUTs 3; transmitting an RRC connection setup message 2222 to each of the communication DUTs 3 by the testing device 1; and transmitting an RRC connection setup complete message 2224 to the testing device 1 by each of the communication DUTs 3. Similarly, the detailed procedures 2220, 2222 and 2224, may be executed in parallel, or may be alternately executed by the processor 13 of the testing device 1.

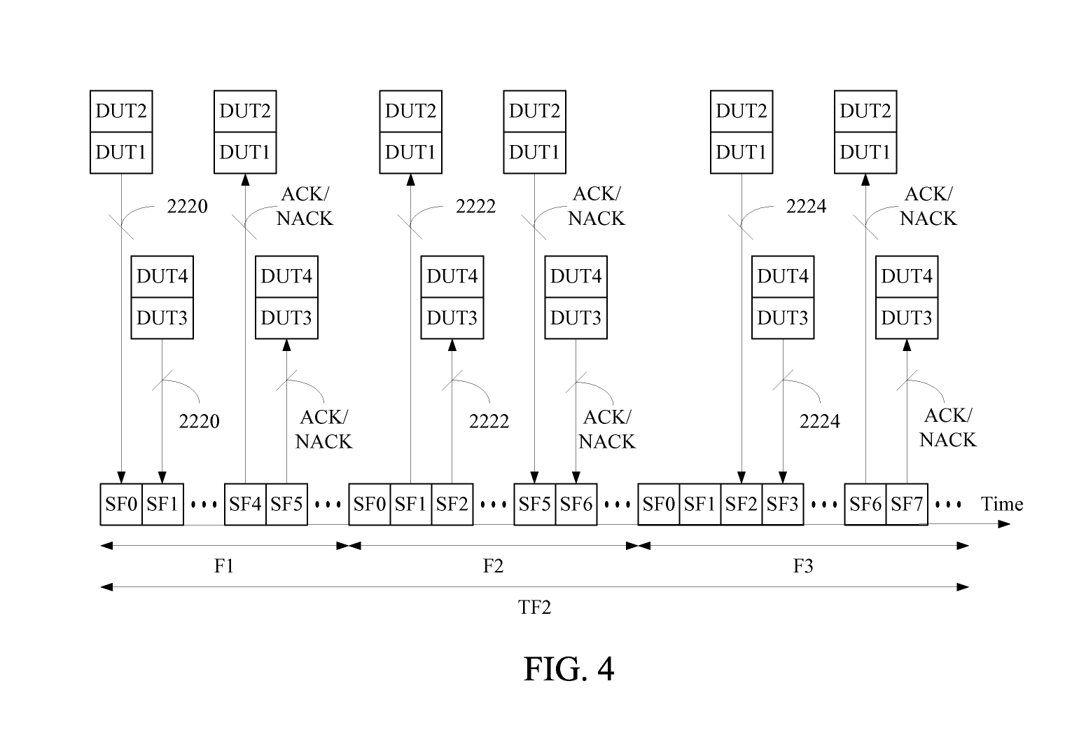

FIG. 4 is a schematic view illustrating an example in which the processor 13 executes the detailed procedures 2220, 2222 and 2224 of the RRC connection establishment procedure 222 with the communication DUTs 3. It is assumed that the processor 13 executes the RRC connection establishment procedure 222 with four communication DUTs 3 (i.e., DUT1, DUT2, DUT3 and DUT4) in the time frame TF2. The time frame TF2 comprises a plurality of frames (e.g., frames F1, F2, F3 and so on), and each of the frames comprises a plurality of sub-frames (i.e., ten sub-frames named as SF0, SF1, SF2, SF3, SF4, SFS, SF6, SF7, SF8, SF9).

The processor 13 of the testing device 1 may receive RRC connection requests 2220 from a plurality of communication DUTs 3 (e.g., the communication DUTs DUT1 and DUT2, the communication DUTs DUT1, DUT2 and DUT3, or the communication DUTs DUT1, DUT2, DUT3 and DUT4) in parallel in anyone of sub-frames of the frame F1. Optionally, after receiving the RRC connection requests 2220 from some communication DUTs 3 in a sub-frame of the frame F1, the processor 13 of the testing device 1 may transmit Acknowledgement (ACK)/Negative Acknowledgement (NACK) messages to the communication DUTs 3 in another sub-frame of the frame F1. For example, the sub-frame where the processor 13 transmits the ACK/NACK is four sub-frames apart from one where the processor receives the RRC connection requests 2220.

The processor 13 of the testing device 1 may transmit RRC connection setup messages 2222 to a plurality of communication DUTs 3 (e.g., the communication DUTs DUT1 and DUT2, the communication DUTs DUT1, DUT2 and DUT3, or the communication DUTs DUT1, DUT2, DUT3 and DUT4) in parallel in anyone of sub-frames of the frame F2. Optionally, after transmitting the RRC connection setup messages 2222 to some communication DUTs 3 in a sub-frame of the frame F2, the processor 13 of the testing device 1 may receive ACK/NACK messages from the communication DUTs 3 in another sub-frame of the frame F2. For example, the sub-frame where the processor 13 receive the ACK/NACK is four sub-frames apart from one where the processor transmits the RRC connection setup messages 2222.

The processor 13 of the testing device 1 may receive RRC connection setup complete messages 2224 from a plurality of communication DUTs 3 (e.g., the communication DUTs DUT1 and DUT2, the communication DUTs DUT1, DUT2 and DUT3, or the communication DUTs DUT1, DUT2, DUT3 and DUT4) in parallel in anyone of sub-frames of the frame F3. Optionally, after receiving the RRC connection setup complete messages 2224 from some communication DUTs 3 in a sub-frame of the frame F3, the processor 13 of the testing device 1 may transmit ACK/ NACK messages to the communication DUTs 3 in another sub-frame of the frame F1. For example, the sub-frame where the processor 13 transmits the ACK/NACK is four sub-frames apart from one where the processor receives the RRC connection setup complete messages 2224.

As shown in FIG. 4, for example, the processor 13 of the testing device 1 may receive RRC connection requests 2220 from the communication DUTs DUT1 and DUT2 in parallel in the sub-frame SF0 of the frame F1, and receive RRC connection requests 2220 from the communication DUTs DUT3 and DUT4 in parallel in the sub-frame SF1 of the frame F1. Then, the processor 13 of the testing device 1 may transmit ACK/NACK messages to the communication DUTs DUT1 and DUT2 in parallel in the sub-frame SF4 of the frame F1, and transmit ACK/NACK messages to the communication DUTs DUT3 and DUT4 in parallel in the sub-frame SF5 of the frame F1.

Next, the processor 13 of the testing device 1 may transmit RRC connection setup messages 2222 to the communication DUTs DUT1 and DUT2 in parallel in the sub-frame SF1 of the frame F2, and transmit RRC connection setup messages 2222 to the communication DUTs DUT3 and DUT4 in parallel in the sub-frame SF2 of the frame F2. Then, the processor 13 of the testing device 1 may receive ACK/NACK messages from the communication DUTs DUT1 and DUT1 in the sub-frame SF5 of the frame F2, and receive ACK/NACK messages from the communication DUTs DUT3 and DUT4 in the sub-frame SF6 of the frame F2.

Finally, the processor 13 of the testing device 1 may receive RRC connection setup complete messages 2224 from the communication DUTs DUT1 and DUT2 in the sub-frame SF2 of the frame F3, and receive RRC connection setup complete messages 2224 from the communication DUTs DUT3 and DUT4 in parallel in the sub-frame SF3 of the frame F3. Then, the processor 13 of the testing device 1 may transmit ACK/NACK messages to the communication DUTs DUT1 and DUT2 in the sub-frame SF6 of the frame F3, and transmit ACK/NACK messages to the communication DUTs DUT3 and DUT4 in the sub-frame SF7 of the frame F3.

After finishing one of the network attaching procedures 20, the processor 13 of the testing device 1 may test the corresponding communication DUT 3. Alternatively, the processor 13 of the testing device 1 may test all the corresponding communication DUT 3 together until all the network attaching procedures 20 are finished.

In an example of this embodiment, the testing device 1 may optionally comprise a display 15 which is electrically connected with the processor 13. The display 15 may be configured to display a network attaching result after each of the network attaching procedures 20 is executed completely. The display may also be configured to display a network attaching result after all the network attaching procedures 20 are executed completely. The display may also be configured to display the network attaching result according to the user's needs.

In an example of this embodiment, each of the communication DUTs 3 may have a device identification. Each device identification may be unique and can be identified by the processor 13 of the testing device 1. Therefore, the processor 13 of the testing device 1 can appropriately schedule all the network attaching procedures 20 to be executed according to the device identifications.

In an example of this embodiment, the processor 13 of the testing device 1 may individually detect an execution status of each of the network attaching procedures 20. In addition, as the processor 13 detects an execution status of one network attaching procedures 20, the display 15 can show information about the execution status.

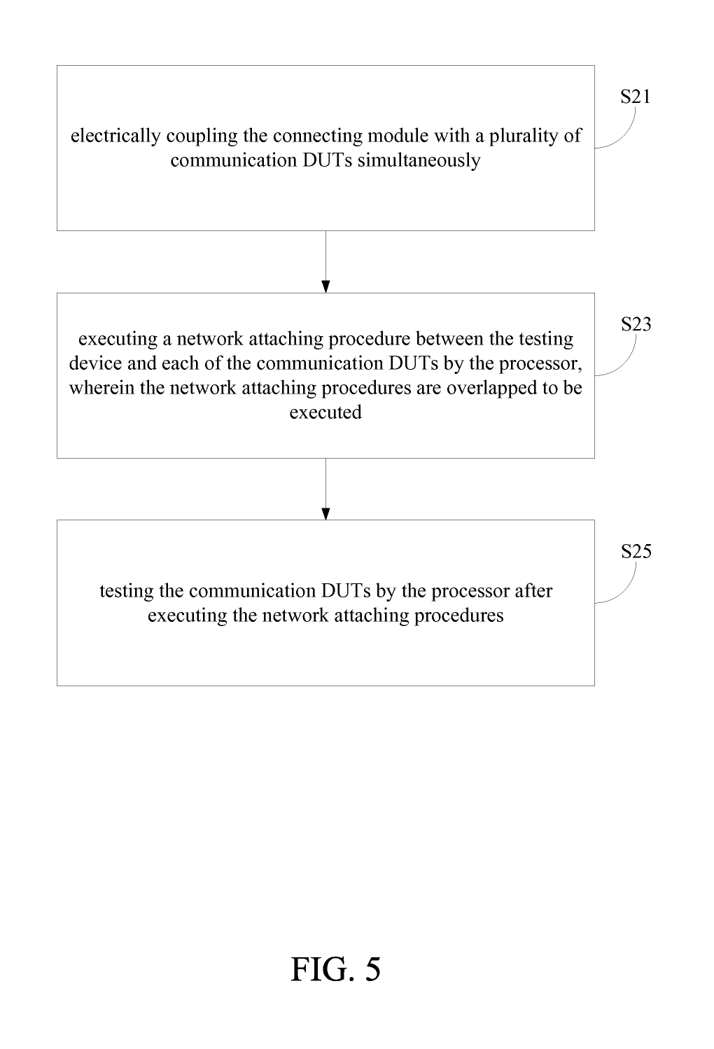

Another embodiment of the present invention (briefly called as “the second embodiment” hereinafter) is a testing method for use in a testing device of a signaling mode. A flowchart diagram of the testing method is shown in FIG. 5. The testing method of this embodiment may be applied to the testing device 1 set forth in the first embodiment. The testing device and the communication DUTs of this embodiment may be considered as the testing device 1 and the communication DUTs 3 of the first embodiment respectively. Therefore, the testing device described of this embodiment may comprise a connecting module and a processor which is electrically connected with the connecting module.

As shown in FIG. 5, the testing method comprises a step S21, a step S23 and a step S25. The order of the steps is not intended to limit the present invention. The step S21 is implemented to electrically couple the connecting module with a plurality of communication DUTs simultaneously. The step S23 is implemented to execute a network attaching procedure between the testing device and each of the communication DUTs by the processor, wherein the network attaching procedures are overlapped to be executed. The step S25 is implemented to test the communication DUTs by the processor after executing the network attaching procedures.

In an example of this embodiment, each of the network attaching procedures may comprise a plurality of sub-procedures. In addition, the step S23 may comprise the step of: executing corresponding sub-procedures of the network attaching procedures in parallel by the processor. The sub-procedures of each of the network attaching procedures may comprise a cell selection procedure, a radio connection procedure, a network connection procedure, and a service connection procedure.

In an example of this embodiment, each of the network attaching procedures may comprise a plurality of sub-procedures. In addition, the step S23 may comprise the step of: alternately executing corresponding sub-procedures of the network attaching procedures by the processor. The sub-procedures of each of the network attaching procedures may comprise a cell selection procedure, a radio connection procedure, a network connection procedure, and a service connection procedure.

In an example of this embodiment, the testing device may further comprise a display which is electrically connected with the processor. In addition, the testing method may further comprise the following step: displaying a network attaching result of the communication DUTs after each of the network attaching procedure is executed.

In an example of this embodiment, each of the communication DUTs may have a device identification, and the step S23 may comprise the step of: scheduling the network attaching procedures to be executed according to the device identifications by the processor.

In an example of this embodiment, the testing method may further comprise the step of: individually detecting an execution status of each of the network attaching procedures by the processor.

The testing method described of this embodiment substantially comprises all the steps corresponding to the operations of the testing device 1 set forth in the first embodiment. Since steps which are not described in this embodiment can be readily appreciated by persons of ordinary skill in the art based on the explanations of the first embodiment, they will not be further described herein.

According to the above descriptions, the present invention provides a testing device of a signaling mode and a testing method thereof. Due to the aforesaid connecting module, the testing device are electrically coupled with a plurality of communication DUTs simultaneously to save the time that would otherwise be taken to couple the testing device repeatedly each time a communication device is tested. Due to the aforesaid processor, the network attaching procedure necessary for the plurality of communication DUTs are overlapped to be executed by the testing device to shorten the time necessary for establishing the network connections between the testing device and the plurality of communication DUTs. The testing method is applied to the testing device to implement the aforesaid operations. Consequently, the present invention can effectively improves the testing efficiency of a conventional testing device of the signaling mode.

The above disclosure is related to the detailed technical contents and inventive features thereof. Persons skilled in the art may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A testing device of a signaling mode, comprising:
a connecting module, configured to electrically coupled with a plurality of communication devices under test (DUTs) simultaneously; and
a processor, electrically connected with the connecting module and configured to execute a network attaching procedure between the testing device and each of the communication DUTs and test the communication DUTs after executing the network attaching procedures;
wherein the network attaching procedures are overlapped to be executed.

2. The testing device as claimed in claim 1, wherein each of the network attaching procedures comprises a plurality of sub-procedures, and the processor executes corresponding sub-procedures of the network attaching procedures in parallel.

3. The testing device as claimed in claim 2, wherein the sub-procedures of each of the network attaching procedures comprises a cell selection procedure, a radio connection procedure, a network connection procedure, and a service connection procedure.

4. The testing device as claimed in claim 1, wherein each of the network attaching procedures comprises a plurality of sub-procedures, and the processor executes corresponding sub-procedures of the network attaching procedures alternately.

5. The testing device as claimed in claim 4, wherein the sub-procedures of each of the network attaching procedures comprises a cell selection procedure, a radio connection procedure, a network connection procedure, and a service connection procedure.

6. The testing device as claimed in claim 1, further comprising a display electrically connected with the processor; wherein the display is configured to display a network attaching result after each of the network attaching procedure is executed.

7. The testing device as claimed in claim 1, wherein each of the communication DUTs has a device identification, and the processor schedules the network attaching procedures to be executed according to the device identifications.

8. The testing device as claimed in claim 1, wherein the processor is further configured to individually detect an execution status of each of the network attaching procedures.

9. A testing method for use in a testing device of a signaling mode, the testing device comprising a connecting module and a processor electrically connected with the connecting module, the testing method comprising:
(a) electrically coupling the connecting module with a plurality of communication DUTs simultaneously;
(b) executing a network attaching procedure between the testing device and each of the communication DUTs by the processor, wherein the network attaching procedures are overlapped to be executed; and
(c) testing the communication DUTs by the processor after executing the network attaching procedures.

10. The testing method as claimed in claim 9, wherein each of the network attaching procedures comprises a plurality of sub-procedures, and the step (b) comprises the step of:
executing corresponding sub-procedures of the network attaching procedures in parallel by the processor.

11. The testing method as claimed in claim 10, wherein the sub-procedures of each of the network attaching procedures comprises a cell selection procedure, a radio connection procedure, a network connection procedure, and a service connection procedure.

12. The testing method as claimed in claim 9, wherein each of the network attaching procedures comprises a plurality of sub-procedures, and the step (b) comprises the step of: alternately executing corresponding sub-procedures of the network attaching procedures by the processor.

13. The testing method as claimed in claim 12, wherein the sub-procedures of each of the network attaching procedures comprises a cell selection procedure, a radio connection procedure, a network connection procedure, and a service connection procedure.

14. The testing method as claimed in claim 9, wherein the testing device further comprises a display electrically connected with the processor, and the testing method further comprises the step of: displaying a network attaching result of the communication DUTs after each of the network attaching procedure being executed.

15. The testing method as claimed in claim 9, wherein each of the communication DUTs has a device identification, and the step (b) comprises the step of: scheduling the network attaching procedures to be executed according to the device identifications by the processor.

16. The testing method as claimed in claim 9, further comprising the step of: individually detecting an execution status of each of the network attaching procedures by the processor.
